(19) United States
(12) Patent Application Publication
(10) Pub. No.: US 2026/0355720 A1
(43) Pub. Date: Nov. 12, 2026

(54) COATED PARTICLES AND METHODS OF MANUFACTURE THEREOF

(71) Applicant: Alei Ahmadi KASANI, Willington, CT (US)

(72) Inventor: Alei Ahmadi KASANI, Willington, CT (US)

(21) Appl. No.: 19/719,961

(22) Filed: Jun. 25, 2026

Related U.S. Application Data
(63) Continuation of application No. PCT/US2025/018324, filed on Mar. 4, 2025.
(60) Provisional application No. 63/560,943, filed on Mar. 4, 2024.

(51) Int. Cl. B01J 23/66; B01J 35/53; B01J 37/02

(52) U.S. Cl. CPC B01J 23/66; B01J 35/53; B01J 37/0221; B01J 37/0238

(57) ABSTRACT

Disclosed herein is a composition comprising a core particle; and a shell; where the shell has a different composition from the core particle and is disposed on the core to form a core-shell particle; where the shell is homogeneous having a thickness of 500 micrometers or less and covers a part or the entire outer surface of the core particle; and where the shell is deposited via physical vapor deposition. Disclosed herein too is a method of producing core-shell particles, the method comprising disposing core particles on a substrate holder that lies in a vacuum chamber; applying a vibration to the substrate holder to produce a resonance in the core particles; fluidizing the core particles by virtue of the applied vibration or fluidizing the core particles in the substrate holder with a stream of fluid; irradiating the core particles with an ion beam to etch, dope or increase surface area of the core particles; and coating the core particles with a shell using physical vapor deposition.

### CROSS-REFERENCE TO RELATED APPLICATIONS

This continuation application claims the benefit of and priority to International Patent Application No. PCT/US2025/018324, filed Mar. 4, 2025, which claims priority to U.S. Provisional Patent Application No. 63/560,943, filed Mar. 4, 2024, each of which are incorporated by reference in their entireties herein.

### TECHNICAL FIELD

The present invention relates to a composition comprising a core particle; and a shell; where the shell has a different composition from the core particle and is disposed on the core to form a core-shell particle; where the shell is homogeneous having a thickness of 500 micrometers or less and covers a part or the entire outer surface of the core particle; and where the shell is deposited via physical vapor deposition. Disclosed herein too is a method of producing core-shell particles, the method comprising disposing core particles on a substrate holder that lies in a vacuum chamber; applying a vibration to the substrate holder to produce a resonance in the core particles; fluidizing the core particles by virtue of the applied vibration or fluidizing the core particles in the substrate holder with a stream of fluid; irradiating the core particles with an ion beam to etch, dope or increase surface area of the core particles; and coating the core particles with a shell using physical vapor deposition.

### BACKGROUND

This disclosure relates to coated particles and methods of manufacture thereof. In particular, this disclosure relates to plasma vapor deposition on core particles in a fluidized state.

Coatings on core particles (of size 2 nanometers to 500 micrometers) can enhance the properties of core particles by providing them with characteristics such as improved wear resistance, corrosion resistance, hardness, and surface smoothness. This is beneficial in applications where these particles are used in harsh environments or subjected to abrasive conditions.

Achieving uniform coating thickness and coverage on particles can be challenging. Variations in particle size, shape, and surface morphology can lead to uneven coating distribution, which may affect the performance and consistency of the coated particles. Coating particles can sometimes lead to agglomeration or clumping of particles, especially if the coating has strong adhesive properties or electrostatic attraction. This can affect the flowability, dispersibility, and handling of the coated particles, posing challenges in various applications.

During the coating process, contaminants from the coating material or the deposition chamber may inadvertently adhere to the particle surfaces, affecting their properties or causing unwanted reactions. Contamination control is crucial to ensure the quality and consistency of the coated particles.

In order to overcome these drawbacks, it is desirable to develop processes where particles can be uniformly coated while reducing detrimental features such as agglomeration and contamination.

### SUMMARY

Disclosed herein is a composition comprising a core particle; and a shell; where the shell has a different composition from the core particle and is disposed on the core to form a core-shell particle; where the shell is homogeneous having a thickness of 500 micrometers or less and covers a part or the entire outer surface of the core particle; and where the shell is deposited via physical vapor deposition.

Disclosed herein too is a method of producing core-shell particles, the method comprising disposing core particles on a substrate holder that lies in a vacuum chamber; applying a vibration to the substrate holder to produce a resonance in the core particles; fluidizing the core particles by virtue of the applied vibration or fluidizing the core particles in the substrate holder with a stream of fluid; irradiating the core particles with an ion beam to etch, dope or increase surface area of the core particles; and coating the core particles with a shell using physical vapor deposition.

### BRIEF DESCRIPTION OF FIGURES

FIG. 1 is a schematic depiction of an exemplary physical vapor deposition chamber that may be used to deposit one or multiple shell layers on the core particles.

FIGS. 2A-D are transmission electron microscopy (TEM) images of the disclosed core shell structure. FIGS. 2A-B are TEM images of iridium (Ir) which is disposed on titanium dioxide (TiO₂) to generate iridium doped titanium dioxide (Ir@TiO₂) core shell. FIGS. 2C-D are TEM images of iridium oxide (IrOx) which is disposed on niobium titanium oxide (NbTiOx) to generate iridium oxide doped niobium titanium oxide (IrOx@NbTiOx) core shell.

FIG. 3 is a schematic depiction of titanium dioxide (TiO₂), or titanium niobium oxide (TiNbOx)-based the core, platinum-based middle layer and iridium-based shell. The platinum-based middle layer increases the conductivity of the core-shell structure. The schematic depiction is created by Solidworks, a solid modeling computer-aided design software.

FIG. 4 describes a durability test of iridium oxide doped niobium titanium oxide (IrOx@NbTiOx) oxygen evolution reaction (OER) anode in a proton exchange membrane (PEM) water electrolyzer. IrOx@NbTiOx catalyst for water electrolyzer anode catalyst durability in a PEM water electrolyzer with Nafion 115, 0.1 mg/cm² Ir and 0.3 mg/cm² platinum loading.

FIG. 5 describes the performance of iridium oxide doped niobium titanium oxide (IrOx@NbTiOx) catalyst for water electrolyzer anode catalyst performance in a PEM water electrolyzer. IrOx@NbTiOx catalyst for water electrolyzer anode catalyst performance in a PEM water electrolyzer with Nafion 115, 0.1 mg/cm² Ir and 0.3 mg/cm2 platinum loading.

### DETAILED DESCRIPTION

Disclosed herein is a method of uniformly coating fine particles to produce a core-shell type particle (hereinafter “core-shell particles”). The core and the shell have different chemical compositions. The fine particles (hereinafter “core particles”) have particle sizes ranging from 2 nanometers to 500 micrometers prior to coating them with a shell. The shell is homogeneous or non-homogenous and preferably has a fairly uniform thickness on the outer surface of the core particle. The shell may be crystalline or amorphous. In a preferred embodiment, the shell is amorphous.

The coating method comprises physical vapor deposition (PVD). The core particles are disposed in a fluidized bed during the coating method. The core particles can be coated with materials that comprise a metal or a ceramic. The core particles can comprise metals, organic material, biomaterial, ceramics, polymers, or a combination thereof.

PVD coatings can also be used to dispose a shell on the core particles for specific purposes. For instance, the core particles can be coated with materials that improve their electrical or thermal conductivity, thermal stability, or biocompatibility, depending on the intended application. In certain industries like cosmetics or automotive, PVD coatings are applied to core particles to impart aesthetic qualities such as color, gloss, or reflectivity. These coatings can create visually appealing effects and improve the overall appearance of the particles. PVD coatings can act as a protective barrier for core particles, shielding them from environmental factors such as moisture, oxidation, and chemical exposure. This helps to prolong the lifespan and performance of the particles, especially in applications where they are exposed to harsh conditions.

Core shell particles are useful in processes such as proton exchange membrane electrolysis for producing green hydrogen. In such processes, reducing precious metal catalyst loading is of value. The catalysts used in the electrolyzer comprises precious metal particles. Since only the surface of the catalyst particles are used in catalytic reactions, the interior of the particles is often being wasted. A core-shell structure in the precious metal constitutes the shell (e.g., Iridium), and a low-cost core (e.g., titanium dioxide) reduces the wasting of precious metals as well as the cost of equipment.

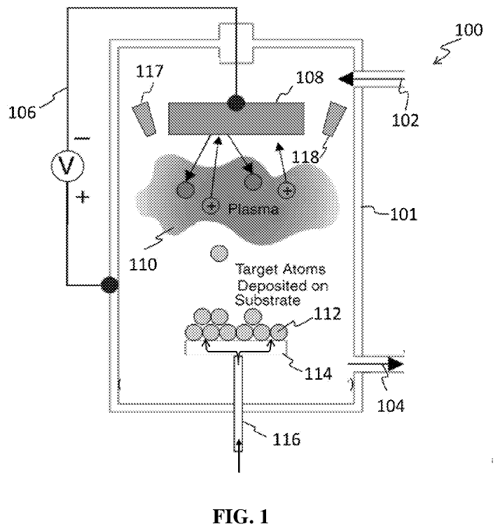

FIG. 1 depicts a physical vapor deposition device 100 that comprises a chamber 101 in which a target material 108 is located at an opposing end from a substrate 112. The substrate 112 is located at a first end of the chamber 101, while the target 108 is located at a second end of the chamber. The second end and the first end lie at opposite ends of the chamber 101. The chamber 101 is preferably a vacuum chamber. The chamber 101 is evacuated to create a low-pressure environment for vaporizing the target material 108 and depositing it onto the substrate 112. The target material 108 is deposited onto the substrate 112 and is often in the form of a solid target, such as a metal or alloy. This target material 108 is placed inside the chamber 101.

The substrate 112 is placed in a substrate holder 114. The substrate holder 114 is a platform or fixture that holds the substrate 112 (the material being coated) in place during the physical vapor deposition process. The substrate holder 114 can be heated to enhance adhesion or control the properties of the deposited film. The substrate holder which can be rotating and/or shaking is also in vibrational communication with one or multiple additional motors that facilitates vibration of the substrate holder at a frequency or a combination of different frequencies that is sufficient to produce resonance and fluidization in the core particles (the substrate 112). The core particles are preferably coated at the resonant frequency.

The chamber 101 is in electrical communication with a power source 106. Typically, a high-voltage power source 106 is used to apply electrical energy to the target material 108. This energy causes atoms or molecules to be ejected from the target material surface through processes like sputtering or evaporation.

The chamber 101 is also in fluid communication with a pumping system (not shown) through outlet port 104. A system of vacuum pumps (not shown) is used to evacuate the chamber 101 and maintain the desired level of vacuum throughout the deposition process. This pumping system is useful for preventing contamination and ensuring uniform coating deposition.

The chamber 101 is also in fluid communication with a first inlet port 102. The first inlet port 102 is an optional feature and may be used to introduce an inert or reactive gas into the chamber 101. Reactive gases typically are used to modify the properties of the material deposited in the substrate or to facilitate specific deposition reactions. Transparent windows or ports (not shown) in the chamber allow operators to observe the deposition process or monitor the condition of the substrate and coating. Depending on the process requirements, the physical vapor deposition device 100 may include systems for controlling the temperature of the substrate, target, or chamber environment to optimize deposition conditions. The physical vapor deposition device 100 also contains a deposition control system (not shown), which includes various instruments and controllers for monitoring and adjusting deposition parameters such as pressure, temperature, deposition rate, and film thickness.

In a preferred embodiment, the physical vapor deposition process for depositing a shell on the core particles includes sputtering. Sputtering involves the physical ejection of atoms or molecules from the target 108 through the bombardment of energetic particles, typically ions, onto the target surface. These ejected particles then travel through the vacuum in the chamber and deposit onto a substrate 112, forming a thin film.

In a sputtering process, the target 108 comprises the material to be deposited, and the substrate 112 is the surface onto which the thin film will be deposited. The chamber is evacuated to create a low-pressure environment, usually in the range of 10⁻³ to 10⁻⁷ torr, to minimize collisions between gas molecules and the sputtered atoms.

To initiate sputtering, a high-energy plasma 110 is generated within the vacuum chamber. This plasma 110 consists of ions (usually inert gas ions such as argon) that are accelerated towards the target material by an electric field. When these ions strike the target 108 surface, they transfer their kinetic energy to the target atoms, causing them to be ejected or sputtered from the surface. The impact of the energetic ions dislodges atoms or molecules from the target 108 material, which are then ejected into the chamber 101 (which is under a vacuum). These sputtered atoms travel in straight lines and may undergo collisions with gas molecules or other atoms before reaching the substrate 112.

The sputtered atoms deposit onto the substrate 112, forming a thin film. In an embodiment, when the substrate comprises a plurality of core particles, a homogenous thin film is formed on each core particle. The substrate 112 is typically positioned facing the target 108, allowing the ejected atoms to travel directly towards it. The substrate 108 may be heated to promote adhesion and improve the quality of the deposited film. Various parameters can be controlled to tailor the properties of the deposited thin film, including the composition of the target material (which is detailed below), the energy and flux of the sputtering ions, the pressure and composition of the gas environment in the chamber, and the temperature of the substrate. Monitoring techniques such as mass spectrometry and electron microscopy (scanning or transmission) may be used to characterize the sputtering process and the properties of the deposited film.

In one embodiment, the substrate holder 114 is modified to contain a device that can render the particles in a fluidized state during the deposition of the coating (the shell). The substrate 112 contains particles that are to be coated. The fluidizing of the particles may be conducted by transporting a volume of a fluid through the particles during the deposition of the shell causing them to become suspended. Several different methods may be used for fluidizing the particles. These are listed below.

Conventional Fluidized Bed: In this method, a fluidizing gas (such as argon or nitrogen) is introduced from below a bed of solid particles. As the gas flow rate increases, it overcomes the gravitational forces acting on the particles, causing them to become suspended and behave like a fluid.

Spouted Bed: In a spouted bed, gas is introduced into a bed of particles through a single or multiple nozzles at the bottom. This creates a spout or fountain-like structure of particles within the vessel. The particles circulate in the spout due to the gas velocity, leading to effective mixing and heat transfer.

Pneumatic Transport: This method involves conveying particles pneumatically through a pipeline using a high-velocity gas stream. The particles are entrained in the gas flow and transported through the pipeline to the desired destination.

Vibratory Fluidization: Vibratory fluidization involves subjecting a bed of particles to mechanical vibrations. These vibrations reduce interparticle friction and promote particle movement, leading to fluid-like behavior.

Jet Fluidization: In jet fluidization, high-velocity gas jets are directed into a bed of particles. The kinetic energy of the gas jets fluidizes the particles, causing them to behave like a fluid.

Rotary Fluidized Bed: In this method, particles are fluidized by the action of a rotating drum or vessel. The rotation imparts kinetic energy to the particles, causing them to become suspended in the gas flow.

Liquid Fluidization: In certain applications, such as slurry reactors or wastewater treatment, particles can be fluidized using a liquid instead of a gas. The principles of fluidization remain similar, but the properties of the liquid phase are utilized instead of a gas.

In an embodiment, the core particles that are to be coated constitute the substrate 112 and are fluidized in the substrate holder 114 via a fluidizing gas that enters the substrate holder 114 via a second inlet port 116. The fluidizing gas enters the substrate holder 114 at a flow rate that facilitates the suspension of the particles. Ion beam guns 117 and 118 are used to etch the core particles for doping and/or etching and/or increasing surface area by creating porosity.

The fluidizing gas may include a reactive gas or an inert gas. In an exemplary embodiment, the inert gas may be argon, krypton, nitrogen, helium, neon, radon, xenon, or a combination thereof. Argon is preferred.

In another embodiment, the fluidized bed may be vibrated (perturbed) by vibrating the sample holder 114. The vibration occurs simultaneously with the deposition of the coating on the core particles contained in the sample holder 114. In an embodiment, the average frequency of vibration of the fluidized bed is 0.1 Hz to 1 megahertz (MHz). In an embodiment, the frequency of vibration is preferably 37 kilohertz (KHz) to 40 KHz. The frequency of the vibration (perturbations) may be variable and comprise a variable wave frequency perturbation of 0.1 Hz to 10 MHz.

The vibration may be of a sinusoidal or cosinusoidal perturbation. Cosinusoidal refers to a wave perturbation that follows the formula y=A cos (Bx+C), where A is the amplitude, B is the frequency, and C is the phase shift. Sinusoidal perturbation, on the other hand, follows the formula y=A sin (Bx+C). Vibratory fluidization is preferred. Additionally, the vibration can have other patterns. These include square waves, triangle waves, sawtooth waves, pulse waves and/or complex waves. The square wave alternates between high and low states without any transition, creating a ‘square’ look. The triangle wave has a linear rise and fall, giving it a triangular shape. The sawtooth wave rises linearly to a peak and then drops sharply, resembling the teeth of a saw. The pulse wave consists of a series of pulses or spikes. The noise wave is random, resembling static or ‘white noise’. Lastly, the complex wave is a combination of two or more of the above waveforms.

The core particles (substrates) include metals, ceramics, and/or polymers. The core particles may be solid or porous. They may be crystalline, amorphous, or semi-crystalline. They may be electrically conducting, semiconducting, or electrically insulating. Crystalline core particles are preferred for metals and ceramics. Semi-crystalline particles are preferred for polymers.

Metal core particles that may be used as the substrate 112 includes transition metals, alkali metals, alkaline earth metals, rare earth metals, or a combination thereof. Metal substrates comprise iron, copper, titanium, aluminum, vanadium, molybdenum, nickel, cobalt, silicon, gallium, indium, thallium, zinc, zirconium, tin, antimony, or the like, or a combination thereof.

Suitable alloys that may be used as core particles are stainless steel, carbon steel, titanium-aluminum alloys, ferroalloys, ferroboron, ferrochrome (chromium), ferromagnesium, ferromanganese, ferromolybdenum, ferronickel, ferrophosphorus, ferrotitanium, ferrovanadium, ferrosilicon, Al—Li (aluminum, lithium, sometimes mercury), Alnico (aluminum, nickel, copper), Duralumin (copper, aluminum), Magnalium (aluminum, 5% magnesium), Magnox (magnesium oxide, aluminum), Nambe (aluminum plus seven other unspecified metals), Silumin (aluminum, silicon), Billon (copper, silver), Brass (copper, zinc), Calamine brass (copper, zinc), Chinese silver (copper, zinc), Dutch metal (copper, zinc). Gilding metal (copper, zinc), Muntz metal (copper, zinc), Pinchbeck (copper, zinc), Prince's metal (copper, zinc), Tombac (copper, zinc), Bronze (copper, tin, aluminum, or any other element), Alumel (nickel, manganese, aluminum, silicon), Chromel (nickel, chromium), Cupronickel (nickel, bronze, copper), German silver (nickel, copper, zinc), Hastelloy (nickel, molybdenum, chromium, sometimes tungsten), Inconel (nickel, chromium, iron), Monel metal (copper, nickel, iron, manganese), Mu-metal (nickel, iron), Ni—C (nickel, carbon), Nichrome (chromium, iron, nickel), Nicrosil (nickel, chromium, silicon, magnesium), Nisil (nickel, silicon), Nitinol (nickel, titanium, shape memory alloy), or a combination thereof.

In another embodiment, the core of the particle may include a semiconductor quantum dot. Examples of quantum dots include cadmium selenide (CdSe), cadmium sulfide (CdS), lead sulfide (PbS), Indium Arsenide (InAs), Zinc Sulfide (ZnS), Cadmium Telluride (CdTe), Indium Phosphide (InP), lead telluride (PbTe), copper indium sulfide (CuInS₂), silver sulfide (Ag₂S), ZnS, ZnSe, ZnTe, ZnO, HgS, HgSe, HgTe, MgSe, MgS, ZnSeS, ZnSeTe, ZnSTe, HgSeS, HgSeTe, HgSTe, CdZnS, HgZnS, HgZnSe, HgZnTe, MgZnSe, MgZnS, HgZnTeS, HgZnSeS, HgZnSeTe, HgZnSTe, GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, SnPbSTe, CuInSe₂, CuInS₂, CuInGaSe, CuInGaS, or a combination thereof.

Ceramic substrates include metal oxides, metal carbides, metal nitrides, metal borides, metal silicides, metal oxycarbides, metal oxynitrides, metal boronitrides, metal carbonitrides, metal borocarbides, or the like, or a combination thereof. Examples of ceramics that may be used as the substrate include silicon dioxide, aluminum oxide, titanium dioxide, zirconium dioxide, indium tin oxide, antimony tin oxide, cerium oxide, cadmium-oxide, titanium nitride, silicon nitride, aluminum nitride, titanium carbide, silicon carbide, titanium niobium carbide, stoichiometric silicon boride compounds (SiBn, where n=14, 15, 40, and so on) (e.g., silicon triboride, SiB₃, silicon tetraboride, SiB₄, silicon hexaboride, SiB₆, or the like), or the like, or a combination thereof.

Exemplary metal oxides include zirconates, titanates, aluminates, stannates, niobates, tantalates and rare earth oxides. Exemplary inorganic oxides include aluminum oxide, silicon dioxide, calcium oxide, cerium oxide, copper oxide, titanium dioxide, zinc oxide, zirconium dioxide, tantalum oxide, niobium oxide, yttrium oxide, magnesium oxide, Mg₂SiO₄, MgO, CaTiO₃, MgZrSrTiO₆, MgTiO₃, MgAl₂O₄, WO₃, SnTiO₄, ZrTiO₄, CaSiO₃, CaSnO₃, CaWO₄, CaZrO₃, MgTa₂O₆, MgZrO₃, MnO₂, PbO, Bi₂O₃ and La₂O₃, CaZrO₃, BaZrO₃, SrZrO₃, BaSnO₃, CaSnO₃, MgSnO₃, Bi₂O_{3/2}SnO₂, Nd₂O₃, Pr₇O₁₁, Yb₂O₃, Ho₂O₃, La₂O₃, MgNb₂O₆, SrNb₂O₆, BaNb₂O₆, MgTa₂O₆, BaTa₂O₆, Ta₂O₃, or the like, or a combination comprising at least one of the foregoing oxides. Exemplary metal oxides include Mg₂SiO₄, MgO, CaTiO₃, MgZrSrTiO₆, MgTiO₃, MgAl₂O₄, MgTa₂O₆, MgZrO₃, or the like, or a combination thereof.

One class of metal oxides that may be used in the core particles include perovskites. Exemplary perovskites and perovskite derivatives include barium titanate (BaTiO₃), strontium titanate (SrTiO₃) barium strontium titanate, strontium-doped lanthanum manganate, lanthanum aluminum oxides (LaAlO₃), lanthanum strontium copper oxides (LSCO), yttrium barium copper oxides (YBa₂Cu₃O₇), lead zirconate titanate, lanthanum-modified lead zirconate titanate, or the like, combinations of lead magnesium niobate-lead titanate, or a combination comprising at least one of the foregoing perovskites and perovskite derivatives. Perovskites that exemplify the giant dielectric phenomenon such as, for example, calcium-copper-titanium-oxides (CCTOs) having the formula (I) can also be included:

ACu₃Ti₄O₁₂ (I)

where A is calcium (Ca) or cadmium (Cd).

In another embodiment, perovskites having the formula (II) can be included:

A′_{2/3}Cu₃Ti₃FeO₁₂ (II)
where A′ is bismuth (Bi), yttrium (Y).

In yet another embodiment, perovskites termed lithium and titanium co-doped nickel oxide (LTNO) having the general formula (III) can be included:

LiₓTi_{y}Ni_{1-x-y}O (III)

where x is less than or equal to about 0.3 and y is less than or equal to about 0.1.

The core particles may also comprise organic polymers. Organic polymers may be selected from a wide variety of thermoplastic polymers, blend of thermoplastic polymers, thermosetting polymers, or blends of thermoplastic polymers with thermosetting polymers. The organic polymer may also be a blend of polymers, copolymers, terpolymers, or combinations comprising at least one of the foregoing organic polymers. The organic polymer can also be an oligomer, a homopolymer, a copolymer, a block copolymer, an alternating block copolymer, a random polymer, a random copolymer, a random block copolymer, a graft copolymer, a star block copolymer, a dendrimer, a polyelectrolyte (polymers that have some repeat groups that contain electrolytes), a polyampholyte (a polyelectrolyte having both cationic and anionic repeat groups), an ionomer, or the like, or a combination comprising at last one of the foregoing organic polymers. The organic polymers have number average molecular weights greater than 10,000 grams per mole, preferably greater than 20,000 g/mole and more preferably greater than 50,000 g/mole. The organic polymers have number average molecular weights of up to 2,000,000 g/mole as measured using gel permeation chromatography with a polystyrene standard.

Examples of thermoplastic polymers that can be used in the core particles include polyacetals, polyacrylics, polycarbonates, polyalkyds, polystyrenes, polyolefins, polyesters, polyamides, polyaramides, polyamideimides, polyarylates, polyurethanes, epoxies, phenolics, silicones, polyarylsulfones, polyethersulfones, polyphenylene sulfides, polysulfones, polyimides, polyetherimides, polytetrafluoroethylenes, polyetherketones, polyether ether ketones, polyether ketone ketones, polybenzoxazoles, polyoxadiazoles, polybenzothiazinophenothiazines, polybenzothiazoles, polypyrazinoquinoxalines, polypyromellitimides, polyguinoxalines, polybenzimidazoles, polyoxindoles, polyoxoisoindolines, polydioxoisoindolines, polytriazines, polypyridazines, polypiperazines, polypyridines, polypiperidines, polytriazoles, polypyrazoles, polycarboranes, polyoxabicyclononanes, polydibenzofurans, polyphthalides, polyacetals, polyanhydrides, polyvinyl ethers, polyvinyl thioethers, polyvinyl alcohols, polyvinyl ketones, polyvinyl halides, polyvinyl nitriles, polyvinyl esters, polysulfonates, polysulfides, polythioesters, polysulfones, polysulfonamides, polyureas, polyphosphazenes, polysilazanes, polypropylenes, polyethylenes, polyethylene terephthalates, polyvinylidene fluorides, polysiloxanes, or the like, or a combination thereof.

Examples of thermosetting polymers include epoxy polymers, unsaturated polyester polymers, polyimide polymers, bismaleimide polymers, bismaleimide triazine polymers, cyanate ester polymers, vinyl polymers, benzoxazine polymers, benzocyclobutene polymers, acrylics, alkyds, phenol-formaldehyde polymers, novolacs, resoles, melamine-formaldehyde polymers, urea-formaldehyde polymers, hydroxymethylfurans, isocyanates, diallyl phthalate, triallyl cyanurate, triallyl isocyanurate, unsaturated polyesterimides, or a combination thereof.

A preferred core particle is titanium dioxide having an oval shape.

The core particles (substrates 112) have a particle size of 5 nanometers to 500 micrometers, preferably 10 nanometers to 100 micrometers, preferably 15 nanometers to 50 micrometers. The core particles may have a particle size distribution that is unimodal or multimodal. Core particles having a bimodal or trimodal particle size distribution may be used.

In an embodiment, the core particles may have an aspect ratio (length-to-diameter ratio) of 1.5:1 or greater, 2:1 or greater, 3:1 or greater, 4:1 or greater. Spherical particles or ellipsoidal particles are preferred. Ellipsoidal particles having aspect ratios of 1:5:1 to 3:1 are preferred.

The shell which is disposed on the core particle to form the core-shell particle includes a coating that may comprise a metal, a ceramic or a polymer. The shell is preferably a uniform homogeneous layer that completely surrounds the core. The shell preferably has a uniform thickness around the core particle with a variation of thickness of less than 15%, preferably less than 10%, and more preferably less than 5%, based on the total thickness of the shell.

The shell may be crystalline, amorphous, and/or semicrystalline. In a preferred embodiment, the shell is amorphous. The shell may be amorphous because it has a very low thickness, which causes it to solidify faster than it can crystallize. In other words, the kinetics of solidification (for the atoms of the shell) are more rapid than the kinetics of crystallization.

In another embodiment, the shell may have a thickness that is less than that of one of the dimensions of a unit crystal for the material of the shell. In other words, the shell does not have the requisite thickness for forming a unit crystal thereby leaving the shell amorphous or semicrystalline.

In an embodiment, the shell has a density that is different from that of the core. In another embodiment, the shell has a density that is at least twice that of the core, preferably at least three times that of the core, preferably at least four times that of the core, and more preferably at least five times that of the core.

The shell may comprise a single layer of a metal, ceramic or polymer. In an embodiment, the shell may comprise a plurality layers of a metal, ceramic or polymer, where each successive layer (as measured along the radius from a center of the core to an outer surface of the shell) has a different composition from the preceding layer. In an embodiment, the plurality of layers may comprise a gold inner layer and an iridium outer layer.

As noted above, the coating (to form the shell) may comprise metals, ceramics or polymers. The shell may be conducting, semiconducting or electrically insulating. The metal coating (also referred to herein as the shell) that is disposed on the substrate particles include transition metals, alkali, metals, alkaline earth metals, rare earth metals, or a combination thereof. The transition metals may include noble metals. Noble metals are preferred for the shell. Examples of metals include gold, platinum, iridium, palladium, copper, titanium, molybdenum, zinc, zirconium, aluminum, silver, magnesium, manganese, germanium, antimony, tin, indium, vanadium, or a combination thereof.

The ceramics and polymers that can be used as the shell are listed above and will not be reproduced here in the interests of brevity. In an embodiment, a preferred shell comprises a noble metal. Amorphous noble metals disposed on core particles of metal oxides are desirable. In another embodiment, a preferred shell comprises amorphous iridium, gold, palladium, platinum, or the like, or a combination thereof.

The shell is disposed as a uniform layer on the core particles. The shell preferably has a thickness of 0.1 to 500 nanometers, 0.5 to 10 nanometers, preferably 1 to 8 nanometers, and more preferably 1.5 to 3 nanometers.

In an embodiment, in one method of producing the core-shell particles, a target material that is desired as the shell is used as the target 108 in the chamber 101. The core particles are placed in the substrate holder 114 (see FIG. 1). The chamber is subjected to a vacuum of 1 to 10 millibar. An inert gas may be introduced into the chamber 101. A voltage is applied between the target and the chamber wall as seen in FIG. 1. A gas (preferably an inert gas) is simultaneously introduced into the substrate holder 114 via the second inlet port 114. The substrate holder is simultaneously vibrated using a sinusoidal wave perturbation. The vibration of the sample holder is conducted at a frequency sufficient to produce resonance in the core particles during the coating process. The frequency of vibration may slightly change during the coating process as target atoms are disposed on the core particles.

In a preferred embodiment, the coating is conducted using sputtering, where a plasma is formed in the chamber as detailed above. The sputtering method may include one of the following. Direct current (DC) sputtering, radio frequency (RF) sputtering, magnetron sputtering, ion beam sputtering, ion-assisted sputtering, reactive sputtering, gas flow sputtering, mid-frequency (MF) sputtering, pulsed DC sputtering, high power impulse magnetron sputtering (HiPIMS), or a combination thereof. The sputtering (to form the shell) is conducted for a period of 2 to 20 seconds, preferably 4 to 10 seconds. A shell thickness of 0.1 to 500 nanometers, preferably 0.5 to 1.5 nanometers is disposed on the core particles.

In an embodiment, the core-shell particles may be subjected to etching either prior to forming the shell, after the formation of the shell, or during both (i.e., prior to forming the shell as well as after the formation of the shell). Etching may be conducted to introduce defects in the core and/or shell, to create reactive sites for further covalent or ionic bonding, to alter the shape and size of the core particles or of the core-shell particles, and so on.

Examples of etching involve ion beam etching (IBE), in which the sample material is bombarded with high-energy argon ion beams in a high vacuum chamber; reactive ion beam etching (RIBE), chemically assisted ion beam etching (CAIBE), plasma etching (PE), reactive ion etching (RIE), magnetically enhanced reactive ion etching (MERIE), capacitively coupled plasma (CCP), inductively coupled plasma (ICP), electron cyclotron resonance (ECR), remote plasma source (RPS), helicon wave plasma (HWP), surface wave plasma (SWP), atomic layer etching (ALE), or a combination thereof.

The core-shell particles may be used in a wide variety of applications such as catalysis, medical treatments, powder coatings, fillers for paints, or the like. The method can be used for coating drugs (referred to herein as biologically active agents) or to create nanoparticles that may be bonded (ionically or covalently) to biologically active agents. The nanoparticles may serve as carrier moieties to deliver certain therapeutically active agents.

Biologically active agents that can be treated with the moieties (nanoparticles or microparticles) obtained by this method include biologically active agents include anti-analgesic agents, anti-arrhythmic agents, anti-bacterial agents, anti-cholinergic agents, anti-coagulant agents, anti-convulsant agents, anti-depressant agents, anti-diabetic agents, anti-diuretic agents, anti-fungal agents, anti-hypertensive agents, anti-inflammatory agents, anti-malarial agents, anti-neoplastic agents, anti-nootropic agents, anti-Parkinson agents, anti-retroviral agents, anti-tuberculosis agents, anti-tussive agents, anti-ulcerative agents, anti-viral agents, or the like, or a combination thereof.

While the invention has been described with reference to some embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiments disclosed as the best mode contemplated for carrying out this invention, but that the invention will include all embodiments falling within the scope of the appended claims.

### EXAMPLE

### Example 1

This example, as shown in the Table 1, was conducted to demonstrate one exemplary embodiment of the disclosed core-shell particle in comparison with a UMICORE supplied commercial iridium oxide (IrOx) catalyst. The active surface area per gram of iridium is more than 10 times-higher than the one obtained from UMICORE. As used herein, the term “Fenton metals” refers to transition metals capable of catalyzing the Fenton reaction, wherein the metal undergoes redox cycling between two oxidation states to generate reactive oxygen species, such as hydroxyl radicals, in the presence of hydrogen peroxide or other peroxides. In certain embodiments, the term “Fenton metals” refers to Copper (Cu), Titanium (Ti), Vanadium (V), Zinc (Zn), Chromium (Cr), and Nickel (Ni)

TABLE 1

| | | | | Our | Test Method and |
|---|---|---|---|---|---|
| No. | Element/Property | Unit | UMICORE | Work | Procedure |
| 1 | Ir content* | % w/w | ≥73.00 ≤ 77.00 | ≥46.00 ≤ 48.00 | ICP-OES |
| | | | | | AV GRD-ACC-HU-1267 |
| 2 | Nb content* | % w/w | ≥6.0 ≤ 9.0 | ≥2 ≤ 3 | ICP-OES |
| | | | | | AV GRD-ACC-HU-1267 |
| 3 | Surface Area | m²/g | ≥30 ≤ 50 | ≥180 ≤ 200 | N2 sorption |
| | (BET)* | | | | SOP SOR-024-025 |
| 4 | IrO₂ crystallite | nm | ≥5.0 ≤ 7.0 | | XRD + Rietveld Analysis |
| | size* | | | | SOP ROE-0002 |
| 5 | Drying loss* | % w/w | ≤3.0 | ≤1.8 | TGA |
| | | | | | AV-GRD-ACC-HU-1299 |
| 6 | Cl content* | ppm | ≤3000 | ≤1 | Wickbold |
| | | | | | AV GRD-ACC-HU-1289 |
| 7 | Fe content* | ppm | ≤30 | ≤4 | ICP-OES |
| | | | | | AV GRD-ACC-HU-1267 |
| 8 | Sum of other | ppm | ≤20 | ≤1 | ICP-OES |
| | Fentonmetals (Cu, | | | | AV GRD-ACC-HU-1267 |
| | Ti, V, Zn, Cr, Ni)* | | | | |
| 9 | Particle Size | nm | ≤4000 | ≤5 | TEM Microscopy: AV- |
| | Distribution, | | | | PMC-FC- |
| | Diameter(D95) | | | | |
| 10 | Surface area per | m²/Ir gr | 53 | 650 | |
| | grams of iridium | | | | |

### Example 2

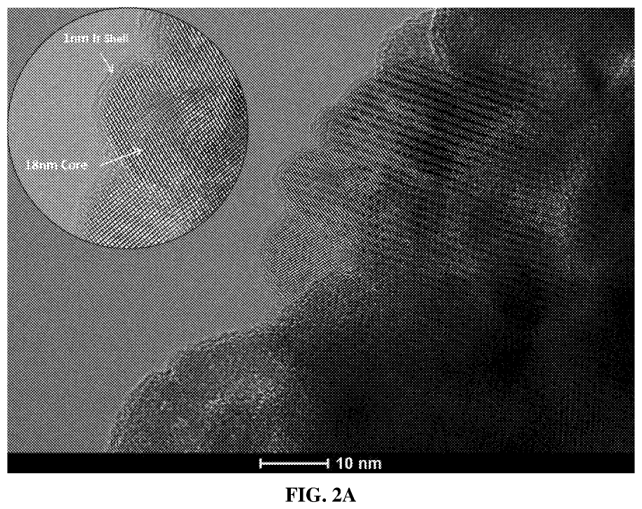

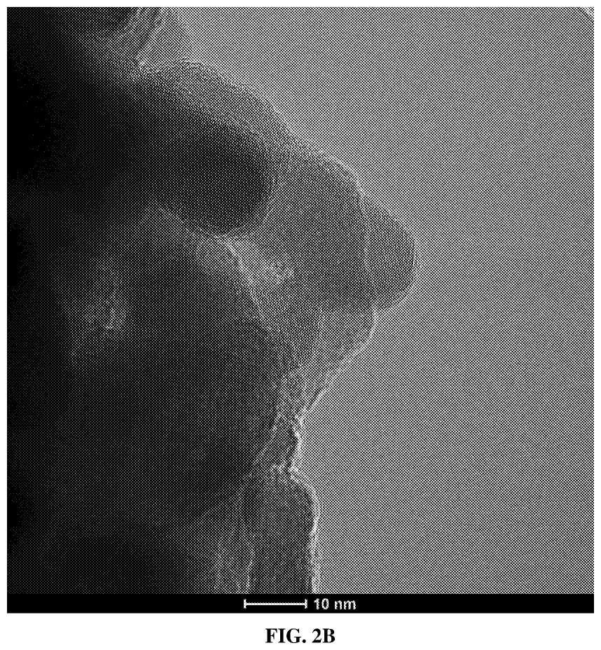

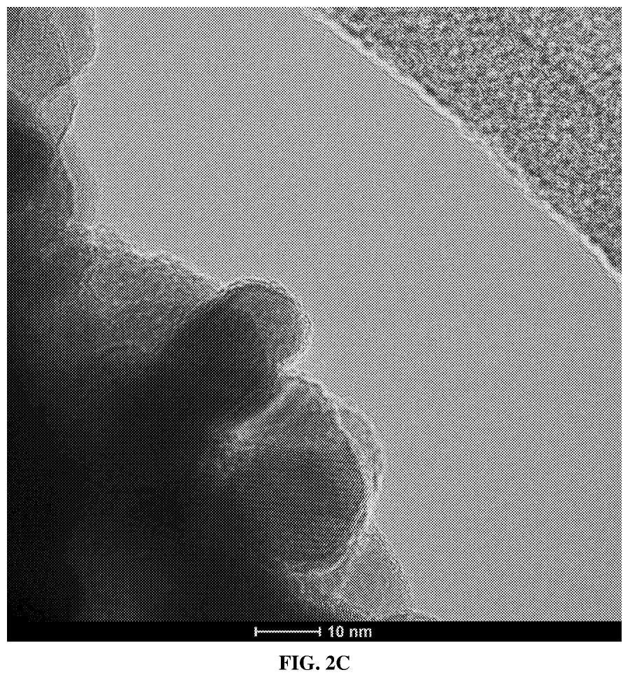

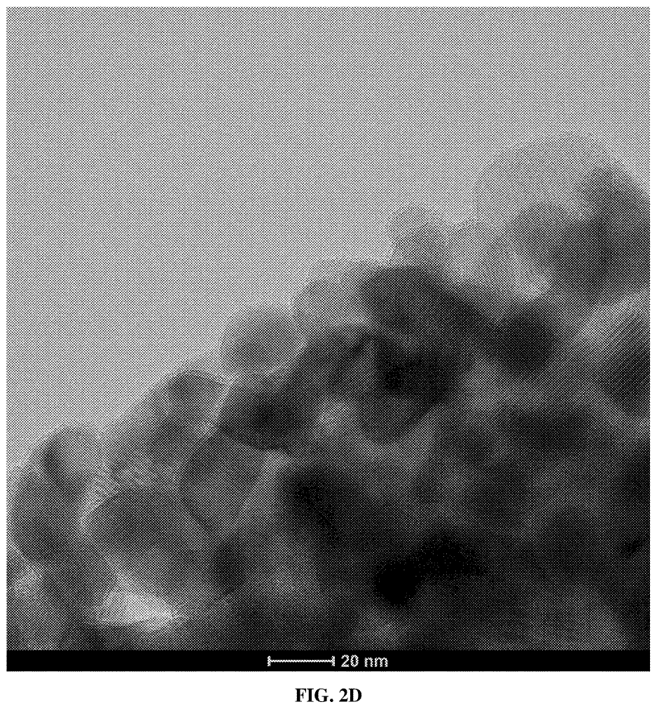

This example, as shown in the FIGS. 2A-D, was conducted to demonstrate one exemplary embodiment of the disclosed core-shell particle. The transmission electron microscopy (TEM) images of the disclosed core shell structure are shown in FIGS. 2A-D. The TEM images of iridium (Ir) which is disposed on titanium dioxide (TiO₂) to generate iridium doped titanium dioxide (Ir@TiO₂) core shell are shown in FIGS. 2A-B. The TEM images of iridium oxide (IrOx) which is disposed on niobium titanium oxide (NbTiOx) to generate iridium oxide doped niobium titanium oxide (IrOx@NbTiOx) core shell are shown in FIGS. 2C-D.

### Example 3

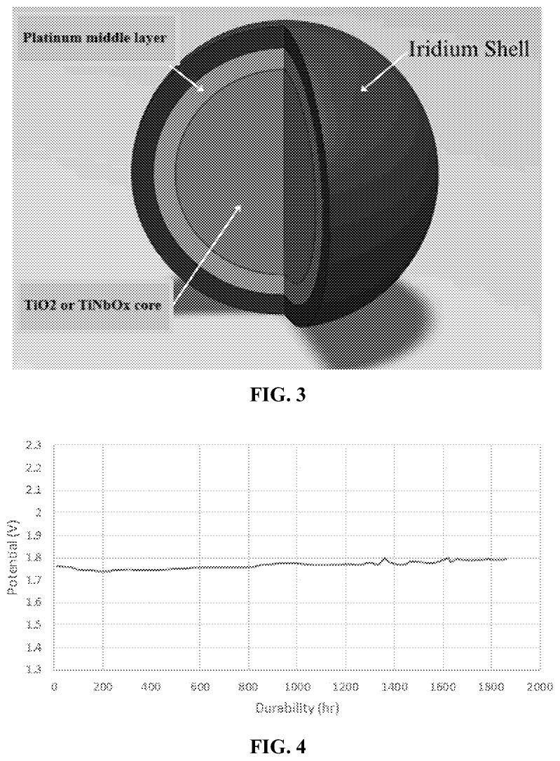

This example, as shown in the FIG. 3, was conducted to demonstrate one exemplary embodiment of the disclosed core-shell particle. A schematic depiction of titanium dioxide (TiO₂), or titanium niobium oxide (TiNbOx)-based the core, platinum-based middle layer and iridium-based shell is shown in FIG. 3. The platinum-based middle layer increases the conductivity of the core-shell structure. The schematic depiction is created by Solidworks, a solid modeling computer-aided design software.

### Example 4

This example, as shown in the FIG. 4, was conducted to demonstrate one exemplary embodiment of the disclosed core-shell particle. A durability test of iridium oxide doped niobium titanium oxide (IrOx@NbTiOx) oxygen evolution reaction (OER) anode in a proton exchange membrane (PEM) water electrolyzer is demonstrated in FIG. 4. IrOx@NbTiOx catalyst for water electrolyzer anode catalyst durability in a PEM water electrolyzer with Nafion 115, 0.1 mg/cm² Ir and 0.3 mg/cm² platinum loading.

### Example 5

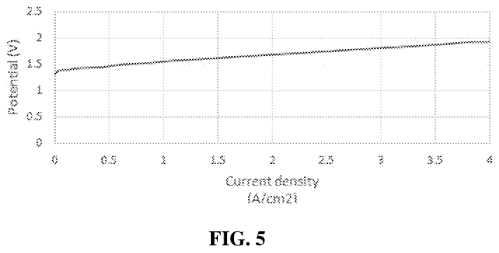

This example, as shown in the FIG. 5, was conducted to demonstrate one exemplary embodiment of the disclosed core-shell particle. The performance of iridium oxide doped niobium titanium oxide (IrOx@NbTiOx) catalyst for water electrolyzer anode catalyst performance in a PEM water electrolyzer is demonstrated. IrOx@NbTiOx catalyst for water electrolyzer anode catalyst performance in a PEM water electrolyzer with Nafion 115, 0.1 mg/cm² Ir and 0.3 mg/cm² platinum loading.

1-14. (canceled)

15. A method of manufacturing coated particles comprising:
disposing core particles on a substrate holder that lies in a vacuum chamber;
applying a vibration to the substrate holder to produce a resonance in the core particles;
optionally fluidizing the core particles by virtue of the applied vibration or fluidizing the core particles in the substrate holder with a stream of fluid;
irradiating the core particles with an ion beam to etch, dope or increase surface area of the core particles; and
coating the core particles with a shell using physical vapor deposition.

16. The method of claim 15, where the vibration comprises a sinusoidal perturbation.

17. The method of claim 15, where the sinusoidal perturbation has a frequency of 0.1 Hz up to 1 MHz.

18. The method of claim 15, further comprising forming a plasma in the vacuum chamber between a target and the substrate holder.

19. The method of claim 15, further comprising introducing an inert gas into the vacuum chamber.

20. The method of claim 15, where a resonance frequency occurs at 37 kHz to 40 kHz.

21. The method of claim 15, where the vibration is applied via a square wave pattern perturbation, a triangle wave pattern perturbation, a sawtooth wave pattern perturbation, a pulse wave pattern perturbation or a complex wave pattern perturbation.

22. The method of claim 15, where the vibration comprises a variable wave frequency perturbation of up to 10 MHz.

23. The method of claim 15, where the fluid comprises an inert gas.

24. The method of claim 15, wherein the shell has a different composition from the core particle and is disposed on the core to form a core-shell particle; wherein the shell is homogeneous having a thickness of 500 micrometers or less and covers a part or the entire outer surface of the core particle; and wherein the shell is deposited via physical vapor deposition.

25. The method of claim 15, wherein the shell has a different composition from the core particle and is disposed on the core to form a core-shell particle; wherein the shell comprises multiple layers, each layer comprising a different metal; wherein the shell has a thickness of 500 micrometers or less and covers a part or the entire outer surface of the core particle; and wherein the shell is deposited via physical vapor deposition.

26. The method of claim 15, wherein the shell thickness is 10 nanometers or less.

27. The method of claim 15, wherein the shell thickness is 2 nanometers or less.

28. The method of claim 15, wherein the shell comprises an amorphous metal.

29. The method of claim 15, wherein the core comprises a crystalline metal oxide.

30. The method of claim 28, wherein the core comprises a crystalline metal oxide.

31. The method of claim 30, wherein the core has an oval cross-sectional area.

32. The method of claim 15, wherein the shell has a density that is at least 2 times that of the core particle.

33. The method of claim 15, wherein the shell has a density that is at least 5 times that of the core particle.

34. The method of claim 28, wherein the amorphous metal is a noble metal.

35. The method of claim 34, wherein the noble metal is iridium, platinum or gold.

36. A coated particle manufactured according to the method of claim 15.

37. A catalyst comprising the coated particle of claim 36.
